(19) United States
(12) Patent Application Publication
(10) Pub. No.: US 2015/0189744 A1
(43) Pub. Date: Jul. 2, 2015

(54) THERMOSETTING RESIN COMPOSITION AND USAGE THEREOF

(71) Applicant: Shengyi Technology Co., Ltd., Guangdong (CN)

(72) Inventors: Xianping ZENG, Guangdong (CN); Nana REN, Guangdong (CN)

(21) Appl. No.: 14/580,321

(22) Filed: Dec. 23, 2014

(30) Foreign Application Priority Data
Dec. 27, 2013 (CN) 201310740712.2

(51) Int. Cl. H05K 1/03; C08L 85/02; H01B 1/02; C08L 63/00

(52) U.S. Cl. CPC H05K 1/0366; C08L 63/00; C08L 85/02; H01B 1/026

(57) ABSTRACT

The present invention relates to a thermosetting resin composition, wherein the resin composition comprises of: (A) epoxy resin; (B) active ester curing agent; (C) poly-phosphonate ester and/or phosphonate-carbonate copolymer. The prepreg and copper clad laminate prepared with the thermosetting resin composition mentioned above has excellent dielectric performance, wet-heat resistance performance, and a flame resistance performance of UL 94 V-0 level.

### TECHNICAL FIELD

The present invention relates to a thermosetting resin composition, particularly to a halogen-free thermosetting resin composition, and prepreg, laminate and high-frequency circuit board made from them.

### BACKGROUND ART

As the information processing of electronic products becomes more and more high-speed and multifunctional and the application frequency is required to increase constantly, 3-6 GHz will be the mainstream, wherein, except a higher requirement is maintained for the heat resistance of the laminate material, lower and lower dielectric constant and dielectric loss value is further pursued. The prior traditional FR-4 is difficult to meet the usage demand of high frequency and rapid development of electronic products. Meanwhile, the substrate material no longer plays the role of mechanical support in the traditional way, and is going to be an important way to improve product performance with the electronic component by the PCB and terminal manufacturer's designers. Because the high D_{K} makes the signal transmission rate slow and high D_{f} make signal partially transfer into heat energy to be lost in the substrate materials, reducing D_{K}/D_{f} has become a hot pursuit of the substrate industry. For the traditional FR-4 material, dicyandiamide is often adopted as curing agent. This curing agent has tertiary reaction amine and good processing property, but its carbon-nitrogen bond is weak and easy to crack at high temperature, thus the thermal decomposition temperature of the curing compound is low and unable to meet the heat-resistance requirements of lead-free process. In this context, with a wide range of lead-free process implementation in 2006, phenolic resin began to be adopted as curing agent for epoxy resin in the industry. Phenolic resin contains high density of heat-resistance structure of benzene ring, therefore after it cured the epoxy resin, the system has excellent heat resistance, but at the same time the dielectric properties of the cured product has the trend of deterioration.

In addition, as the environmental protection requirement of the consumer electronic products become more and more strict, the halogen free requirements for the laminate materials is becoming increasingly common. In order to achieve a same flame resistance effect with halogen element system, at present the principle technical route is phosphorus flame resistance, including phosphorus-containing epoxy resin and phosphorus-containing phenolic aldehyde. In addition, nitrogen-containing flame resistance and inorganic filler are equipped to achieve the halogen-free flame resistance. But the halogen free flame retardant above is involved in the curing reaction of the system in the application field of high frequency and high speed, and the structural properties of the material itself leads to poor dielectric properties, thus the performance requirements of dielectric cannot be met. The traditional phosphate is not involved in the system, is more regular in structure and has better dielectric properties, but the traditional phosphate compounds has the disadvantages of small molecular weight, low melting point and high hygroscopicity, thus it is no longer applied in the copper clad laminates.

### SUMMARY OF THE INVENTION

One object of the present invention is to provide a thermosetting resin composition, which can provide excellent dielectric properties, wet-heat resistance, high Tg, low water absorption and UL 94 V-0 level of halogen-free flame resistance.

To achieve the object above, the present invention employs the following technical solutions:
a thermosetting resin composition, wherein the resin composition comprises of:
(A) epoxy resin;
(B) active ester curing agent;
(C) poly-phosphonate ester and/or phosphonate-carbonate copolymer.

In the present invention poly-phosphonate ester and/or phosphonate-carbonate copolymer is adopted as flame retardant, which has the advantages of high molecular weight, low water absorption and excellent heat resistance.

Preferably, the structural formula of the polyphosphonate ester is as follows:

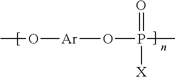

wherein Ar is an aryl, the —O-Ar-O— is any one selected from the group consisting of resorcinol active group, hydroquinone active group, bisphenol A active group, bisphenol F active group, 4,4′-bisphenol, phenolphthalein active group, 4,4′-thiodiphenol active group, 4,4′-sulfonyl diphenol active group and 3,3,5-trimethylcyclohexyl diphenol active group; X is substituted or unsubstituted straight chain alkyl of C1-C20, substituted or unsubstituted branched alkyl of C1-C20, substituted or unsubstituted straight chain alkenyl of C2-C20, substituted or unsubstituted branched alkenyl of C2-C20, substituted or unsubstituted straight chain alkylene of C2-C20, substituted or unsubstituted branched alkylene of C2-C20, substituted or unsubstituted cycloalkyl of C5-C20, or substituted or unsubstituted branched aryl of C6-C20; n is any integer from 1 to 75, such as 2, 5, 8, 10, 15, 20, 25, 30, 35, 40, 45, 50, 55, 60, 65, 70 or 72.

Preferably, the structural formula of the phosphate-carbonate copolymer is as follows:

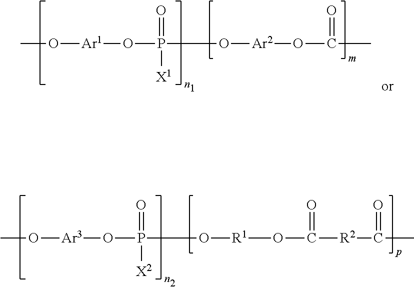

wherein, Ar¹, Ar² and Ar³ are respectively and independently selected from aryl and the —O-Ar3-O— is any one selected from the group consisting of resorcinol active group, hydroquinone active group, bisphenol A active group, bisphenol F active group, 4,4′-bisphenol, phenolphthalein activity group, 4,4′-thiodiphenol active groups, 4,4′-sulfonyl diphenol active group and 3,3,5-trimethylcyclohexyl diphenol active group; X¹ and X² are respectively and independently substituted or unsubstituted straight chain alkyl of C1-C20, substituted or unsubstituted branched alkyl of C1-C20, substituted or unsubstituted straight chain alkenyl of C2-C20, substituted or unsubstituted branched alkenyl of C2-C20, substituted or unsubstituted straight chain alkylene of C2-C20, substituted or unsubstituted branched alkylene of C2-C20, substituted or unsubstituted cycloalkyl of C5-C20, or substituted or unsubstituted branched aryl of C6-C20; m is any integer from 1 to 100, n₁ and n₂ are respectively and independently any integer from 1 to 75, and p is any integer from 2 to 50; R¹, R² are respectively and independently selected from the group consisting of substituted or unsubstituted aliphatic or aromatic hydrocarbon group, preferably selected from unsubstituted aliphatic or aromatic hydrocarbon group.

“Aryl” refers to any functional group or substituent derived from an aromatic ring. Illustrative examples of aromatic ring include methylbenzene, ethylbenzene, n-propylbenzene, isopropylbenzene, styrene, phenol, acetophenone, anisole, ethoxybenzene, benzyl alcohol, benzaldehyde, benzoyl chloride, benzoic acid, cyanobenzene, nitrobenzene, nitrosyl benzene, aniline, fluorobenzene, chlorobenzene, bromobenzene, iodobenzene, benzenesulfonic acid, diphenyl ketone, benzil, phenylacetic acid, mandelic acid, cinnamic acid, acetanilide, phenethylamine, azobenzene, benzene diazonium chloride, benzoyl peroxide, benzyl chloride, benzenesulfonyl chloride, diphenylmethane, triphenylmethane, trityl alcohol, trityl methane chloride, tetraphenyl methane, xylene (o-toluene, m-xylene, p-xylene), dihydroxyhenzene (o-dihydroxybenzene, resorcinol, hydroquinone), phthalic acid (phthalic acid, m-phthalic acid, terephthalic acid), phenylenediamine (o-phenylenediamine, m-phenylenediamine, p-phenylenediamine), toluidine (o-toluidine, m-toluidine, p-toluidine), benzene-m-disulfonic acid, toluene-p-sulfonic acid, p-aminobenzoic acid, salicylic acid, acetylsalicylic acid, acetaminophen, phenacetin, m-chloroperoxybenzoic acid, mesitylene, unsym-trimethyl benzene, durene, gallic acid, pyrogallol, picric acid, trinitrotoluene, tribromo phenol, pentachlorophenol, mellitic acid, biphenyl, terphenyl, naphthalene, anthracene, phenanthrene, benzoquinone (o-benzoquinone, p-benzoquinone), and the aryl can be any functional group or substituent derived from the any aromatic ring mentioned above.

Preferably, the polyphosphonate ester or/and phosphate-carbonate copolymer is any one or a mixture of at least two selected from the group consisting of

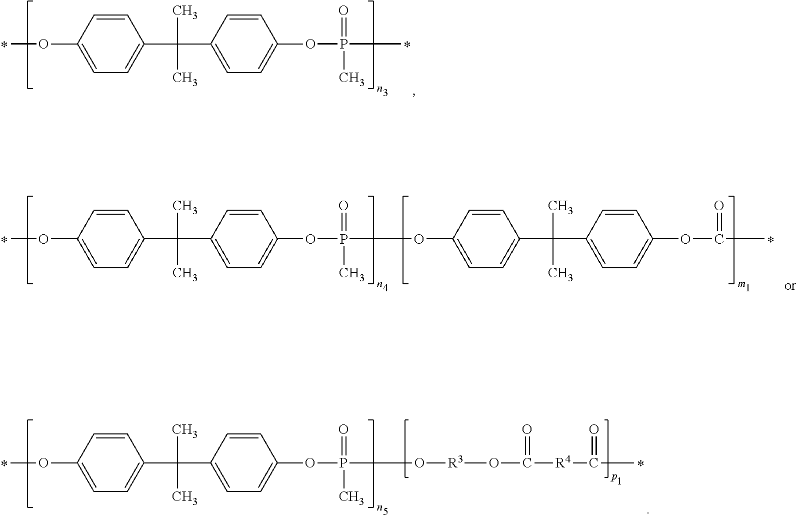

wherein, R³ and R⁴ are respectively and independently selected from substituted or unsubstituted aliphatic or aromatic hydrocarbon groups, preferably selected from unsubstituted aliphatic or aromatic hydrocarbon groups; m₁ is any integer from 1 to 100; n₃, n₄ and n₅ are respectively and independently any integer from 1 to 75; p₁ is any integer from 2 to 50;
preferably, m and m₁ are respectively and independently any integer from 5 to 100, and preferably m and mᵢ are respectively and independently any integer from 10 to 100;
preferably, n₁, n₂, n₃, n₄ and n₅ are respectively and independently any integer from 5 to 75, and preferably n₁, n₂, n₃, n₄ and n₅ are respectively and independently any integer from 10 to 75;
preferably, p and p₁ are respectively and independently any integer from 5 to 50, and
preferably p and p₁ are respectively and independently any integer from 10 to 50;
m and m₁ are respectively and independently such as 2, 5, 10, 15, 20, 25, 30, 35, 40, 45, 50, 55, 60, 65, 70, 75, 80, 85, 90 or 95.
n₁, n₂, n₃, n₄ and n₅ are respectively and independently such as 2, 5, 8, 10, 15, 20, 25, 30, 35, 40, 45, 50, 55, 60, 65, 70 or 72.
p and p₁ are respectively and independently such as 3, 5, 10, 14, 18, 22, 26, 30, 34, 38, 42, 45 or 48.

Preferably, the weight-average molecular weight of the poly-phosphonate ester and/or phosphonate-carbonate copolymer is 1000-60000, preferably 1500-40000 and more preferably 2000-10000. When the weight-average molecular weight is below 1000, after addition to the cured resin, the heat resistance of the cured product will be reduced, for example, the glass transition temperature will decrease; however when the weight-average molecular weight is more than 60000, the poly-phosphonate ester and/or phosphonate-carbonate copolymer has very poor solubility in organic solvent, thus good and uniform resin glue can't be obtained and the technical requirements of copper clad laminate can not be met.

Preferably, the epoxy resin is selected from the epoxy resin with the structure as follows:

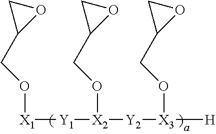

wherein, X₁, X₂, and X₃ are respectively and independently selected from

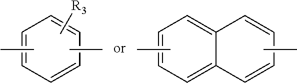

and R₃ is any one selected from the group consisting of hydrogen atom, substituted or unsubstituted straight chain alkyl of C1-C5 and substituted or unsubstituted branched alkyl of C1-C5;

Y₁, Y₂ are any one selected from the group consisting of single bond, —CH2-,

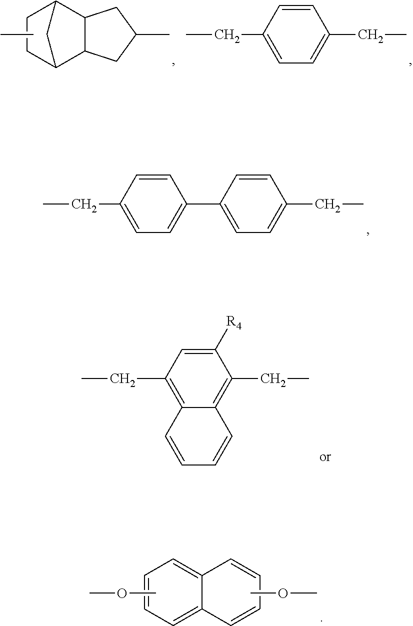

a is any integer from 1 to 10, and R₄ is any one selected from the group consisting of hydrogen atom, substituted or unsubstituted straight chain alkyl of C1-C5 and substituted or unsubstituted branched alkyl and alkoxy of C1-C5;
preferably, the epoxy resin is any one or a mixture of at least two selected from the epoxy resins having the following structural formula:

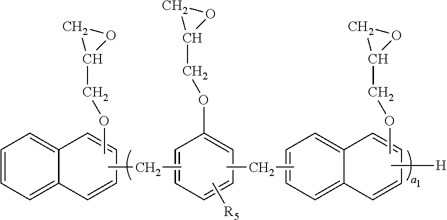

wherein, a₁ is any integer between 1 and 10, and R₅ is any one selected from the group consisting of hydrogen atom, substituted or unsubstituted straight chain alkyl of C1-C5 and substituted or unsubstituted branched alkyl of C1-C5;
or

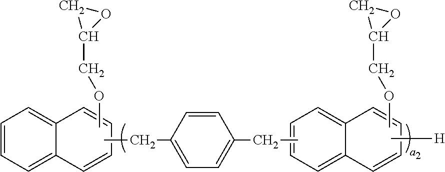

wherein, a₂ is any integer from 1 to 10, such as 2, 3, 4, 5, 6, 7, 8 or 9;
or

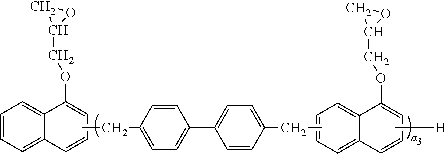

wherein, a₃ is any integer from 1 to 10;
or

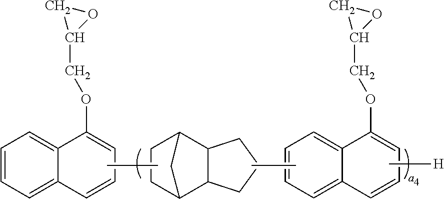

wherein, a₄ is any integer from 1 to 10, such as 2, 3, 4, 5, 6, 7, 8 or 9;
preferably, the epoxy resin is selected from the epoxy resin having the following structure:

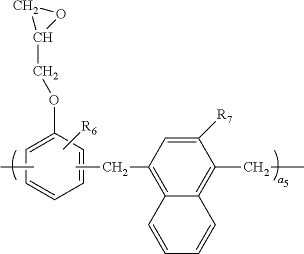

wherein, a₅ is any integer from 1 to 10, such as 2, 3, 4, 5, 6, 7, 8 or 9; R₆ is any one selected from the group consisting of hydrogen atom, substituted or unsubstituted straight chain alkyl of C1-C5 or substituted or unsubstituted branched alkyl of C1-C5; R₇ is any one selected from the group consisting of hydrogen atoms, substituted or unsubstituted straight chain alkyl of C1-C5 or substituted or unsubstituted branched alkyl or alkoxy of C1-C5.

Preferably, the active ester curing agent is prepared from reaction of the phenolic compounds with structural formula of

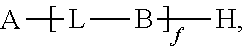

aromatic dicarboxylic acid or acid halides and monohydroxyl compounds; A, B are independently selected from phenolic groups, L is alicyclic group and f is any integer from 1 to 5. The active ester curing agent mainly has the effect of curing epoxy resin. After it cured epoxy resin, there is no generation of secondary hydroxyl, therefore there is no hydroxyl polar groups in the cured product, thereby it has good dielectrical properties, low water absorption rate and good wet-heat resistance.

Preferably, the phenolic compounds with structural formula of

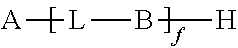

is any one or a mixture of at least two selected from the phenolic compounds having the following structure:

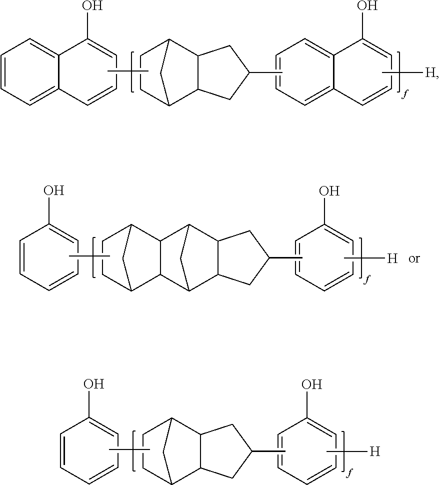

wherein, f is any integer from 1 to 5;
preferably, the aromatic dicarboxylic acid is any one or a mixture of at least two selected from the aromatic dicarboxylic acid having the following structure:

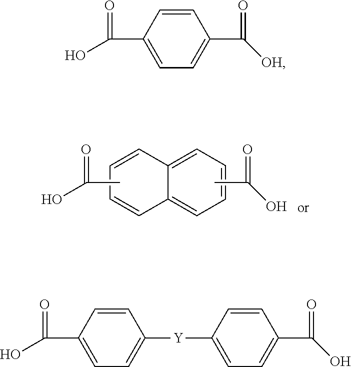

wherein, Y is selected from substituted or unsubstituted strain chain alkylene of C1-C5 or substituted or unsubstituted branched alkylene of C1-C5;
preferably, based on the usage amount of the aromatic dicarboxylic acid or acid halides as 1 mol, the usage amount of the phenolic compound with the structural formula of

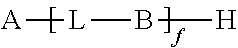

is 0.05-0.75mo1, such as 0.1 mol, 0.15 mol, 0.2 mol, 0.25 mol, 0.3 mol, 0.35 mol, 0.4 mol, 0.45 mol, 0.5 mol, 0.55 mol, 0.6 mol, 0.65 mol or 0.7 mol, and the usage amount of monohydroxyl compounds is 0.25-0.95mol, such as 0.3 mol, 0.35 mol, 0.4 mol, 0.45 mol, 0.5 mol, 0.55 mol, 0.6 mol, 0.65 mol, 0.7 mol, 0.75 mol, 0.8 mol, 0.85 mol or 0.9 mol.

Further, the active ester curing agent has the structural formula as follows:

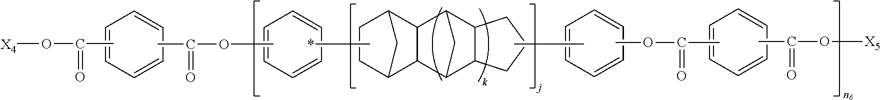

wherein, X₄ and X₅ are independently selected from benzene ring or naphthalene ring, j is 0 or 1, k is 0 or 1, and n₆represents the average repeat unit of 0.25-2.5;
preferably, based on the total weight of component (A) and component (B) as 100 weight parts, the polyphosphonate ester or/and phosphate-carbonate copolymer is 10-100 weight parts, such as 15 weight parts, 20 weight parts, 25 weight parts, 30 weight parts, 35 weight parts, 40 weight parts, 45 weight parts, 50 weight parts, 55 weight parts, 60 weight parts, 65 weight parts, 70 weight parts, 75 weight parts, 80 weight parts, 85 weight parts, 90 weight parts or 95 weight parts, preferably 15-50 weight parts.

There is no special limitation for the addition amount of the polymers or copolymer contained in the phosphate ester of the present invention but making the cured product reach the level of UL 94 V-0. To ensure the cured products has better comprehensive performance, such as heat-resistance, hydrolysis resistance, based on the total weight of component (A), component (B) and component (C) as 100 weight parts, the addition amount of the polymers or copolymer contained in the phosphate ester is 5-30% weight parts, preferably 8-25% weight parts, and further preferably 15-25%.

The usage amount of the active ester curing agent is calculated according to the ratio of epoxy equivalent and active ester equivalent. The equivalent ratio is 0.85-1.2, such as 0.88, 0.92, 0.96, 1, 1.04, 1.08, 1.12 or 1.16, preferably 0.9-1.1 and most preferably 0.95-1.05.

If necessary, the thermosetting resin composition of the present invention can further comprises of component (D) filler. There is no special limitation for the filler added according to need. The filler is selected from organic and/or inorganic filler, preferably the inorganic filler, further preferably the surface-treated inorganic filler, and most preferably, the surface-treated silicon dioxide.

The surface treating agent for surface treatment is any one or a mixture of at least two selected from a group consisting of silane coupling agents, organosilicone oligomer, and titanate coupling agent;

preferably, the silane coupling agents is any one or a mixture of at least two selected from vinyl tri-methoxysilane, vinyltriethoxysilane, glycerol propyl trimethoxy silane, 2-(3,4-epoxy cyclohexyl) ethyltrimethoxy silane, 3-glycidoxy propyl triethoxysilane, 3-glycidoxy methyl dimethoxy silane, p-isobutylene trimethoxy silane, 3-isobutylene propyl triethoxy silane, 3-propyl methacrylate methyldimethoxy silane, 3-propyl methacrylate Methyl dioxolmeth silane, 3-allyl trimethoxysilane, N-2-(aminoethyl)-3-aminopropyl triethoxy silane, 3-aminopropyl triethoxy silane, 3-triethoxysilyl monosilane-N-(1,3-dimethyl-butyl) propylamine, N-phenyl-3-ammonia propyl trimethoxy silane or 3-isocyanate propyl triethoxy silane.

Preferably, based on the inorganic filler of 100 weight parts, the usage amount of the surface treatment agent is 0.1-5.0 weight parts, preferably 0.5-3.0 weight parts, more preferably 0.75-2.0 weight parts.

The inorganic filler is any one or a mixture of at least two selected from the group consisting of nonmetal oxide, metal nitride, non metal nitride, inorganic hydrate, inorganic salt, metal hydrate and inorganic phosphorus; preferably, any one or a mixture of at least two selected from the group consisting of crystalline silica, fused—silica, spherical silica, hollow silica, glass powder, aluminum nitride, boron nitride, silicon carbide, aluminum hydroxide, titanium oxide, strontium titanate, barium titanate, alumina, barium sulfate, talc powder, calcium silicate, calcium carbonate and mica; the mixture is such as the mixture of crystalline silica and fused silica, the mixture of spherical silica and hollow silica, the mixture of glass powder and aluminum nitride, the mixture of boron nitride and silicon carbide, the mixture of aluminum hydroxide and titanium oxide, the mixture of strontium titanate, barium titanate and alumina and the mixture of barium sulfate, talc powder, calcium silicate, calcium carbonate and mica.

The organic filler is any one or a mixture of at least two selected from the group consisting of polytetrafluoroethylene powder, polyphenylene sulfide, organophosphorus compounds and polyether sulfone powder. The mixture is such as the mixture of polytetrafluoroethylene powder and polyphenylene sulfide and the mixture of organophosphorus compounds and polyether sulfone powder.

In addition, there is no specific limitation for shape and particle diameter of the filler. Preferably, the median particle diameter of the filler is 0.01-50 μm, such as 1 μm, 3 μm, 7 μm, 12 μm, 25 μm, 28 μm, 32 μm, 37 μm, 43 μm, 47 μm and 49 μm, preferably 0.01-20 μm, and more preferably 0.1-10 μm. The inorganic filler with this range of particle diameter is easier to disperse in the resin solution.

Furthermore, there is no specific limitation for the addition amount of component (D) the filler. Based on the total weight of the component (A), component (B) and component (C) of 100 weight parts, the addition amount of the component (E) the filler is 5-1000 weight parts, such as 10 weight parts, 80 weight parts, 120 weight parts, 230 weight parts, 350 weight parts, 450 weight parts, 520 weight parts, 680 weight parts, 740 weight parts, 860 weight parts, 970 weight parts, preferably 5-300 weight parts, more preferably 5-200 weight parts, and particularly preferably 15-150 weight parts.

If necessary, the thermosetting resin composition of the present invention can further comprise of component (E) curing promotor. There is no special limitation for the curing promotor but catalyzing reaction of epoxy functional group, reducing the reaction temperature of curing system. Preferably, the curing promoter is any one or a mixture of at least two selected from the group consisting of imidazole compounds and their derivatives, piperidine compounds, lewis acid or triphenyl phosphine; specific example of the imidazole compound include any one or a mixture of at least two selected from the group consisting of 2-methylimidazole, 2-phenylimidazole and 2-ethyl-4-methylimidazole; the specific example of piperidine compound include any one or a mixture of at least two selected from the group consisting of 2,3-diaminopiperidine, 2,5-diaminopip eridine, 2,6-diaminopiperidine, 2,5-diaminopiperidine, 2-amino-3-methylpiperidine, 2-amino-4-4-methylpiperidine, 2-amino-3-nitropiperidine, 2-amino-5-nitropiperidine or 4-dimethylaminopiperidine.

Based on the total weight of component (A), component (B) and component (C) as 100 weight parts, the addition amount of the component (E) curing promoter is 0.01-1 weight parts, such as 0.07 weight parts, 0.2 weight parts, 0.3 weight parts, 0.5 weight parts, 0.7 weight parts, 0.9 weight parts, 0.95 weight parts, preferably 0.05-0.85 weight parts, and more preferably 0.1-0.8 weight parts.

As used herein, the term “comprise” in the present invention means “to also include the other components besides the components mentioned already”. Those “other components” give different characteristics to the resin composition. In addition, the term “comprises” in the present invention also can be replaced by closed type “is” or “consisting of”.

For example, the thermosetting resin composition of the present invention can be added with formulated thermosetting resin. Specific examples of the present invention include polyphenylene ether resin, cyanate ester resin, phenolic resin, polyurethane resin, melamine resin etc. Curing agent or cured agent promotor of the thermosetting resin composition can also be added.

In addition, the thermosetting resin composition can also comprise of various additives. Specific examples of the present invention include antioxidant, heat stabilizer, antistatic agent, ultraviolet absorbent, pigments, colorants, lubricant etc. The thermosetting resin and various additives can be used alone, also can be used in mixture of two or more.

The preparation methods of the resin composition of the present invention can be achieved according to the method disclosed in the prior art by formulating, stirring and mixing component (A), component (B), component (C), curing promotor, filler, various thermosetting resin and various additives.

The resin glue can be obtained by dissolving or dispersing the thermosetting resin composition mentioned above in the solvent.

There is no special limitation for the solvent of the present invention, Specific examples include alcohol solvent of methanol, ethanol, butanol etc., ether solvent of ethyl cellosolve, butyl cellosolve, glycol monomethyl ether, carbitol, butyl carbitol etc., ketone solvent of acetone, butanone, methyl ethyl ketone, methyl isobutyl ketone, cyclohexanone etc., aromatic hydrocarbon solvent of toluene, xylene, 1,3,5-trimethylbenzene etc., ester solvent of ethoxy ethyl acetate, ethyl acetate etc., nitrogen containing solvent of N,N-dimethyl formamide, N, N-dimethyl acetamide, N-methyl-2-pyrrolidone etc. The solvents mentioned above can be used alone or be used in mixture of two or more, preferably, the mixture of aromatic hydrocarbon solvent, such as toluene, xylene, 1,3,5-trimethylbenzene etc., and ketone solvent such as acetone, butanone, methyl ethyl ketone, methyl isobutyl ketone, cyclohexanone etc. The usage amount of the solvent can be chosen by those skilled in the art according to their own experiences, to obtain the viscosity of the resin glue suitable for use.

Emulsifier can be added during the dissolving process or dispersing process of the resin composition mentioned above. The powder filler can be dispersed uniformly in glue solution by dispersion of emulsifier.

The second object of the present invention is to provide a prepreg, which comprises of the enhancement material and the thermosetting resin composition mentioned above, which adhere to the enhancement material after impregnation and then drying. There is no special limitation for the enhancement material, which can be organic fiber, inorganic fiber woven cloth or non-woven fabrics, wherein, the organic fiber is preferably aramid fiber nonwoven, and the inorganic fiber woven cloth is preferably E-glass fiber, D-glass fiber, S-glass fiber, T-glass fiber, NE-glass fiber and quartz cloth. There is no special limitation for the thickness of the enhancement material. In respect of laminate's application, and concerning good dimensional stability, the thickness of the woven cloth or non-woven fabric is preferably 0.01-0.2 mm, and preferably processed through open fiber processing and surface treatment with silane coupling agent. In order to provide good water resistance and heat resistance, the silane coupling agent is preferably any one or a mixture of at least two selected from a group consisting of epoxy silane coupling agent, amino silane coupling agent or any vinyl silane coupling agent. The prepreg is obtained by baking the impregnated prepreg with the thermosetting resin composition for 2-10 minutes at 100-200° C. and drying.

The third object of the present invention is to provide a laminate, which comprises of at least one prepreg mentioned above.

One or a few pieces of prepreg mentioned above are stacked together in certain order, one side or both sides of the stacked prepreg were covered with copper foil and it is cured in the heat press machine to prepare copper clad laminate. The curing temperature is 150-250° C. and the curing pressure is 25-60 kg/cm². The prepreg and the laminate of the present invention have excellent dielectric properties and wet-heat resistance, and they also have high glass transition temperature, low water absorption rate, and meanwhile achieve the halogen-free flame resistance of UL 94 V-0 level.

The fourth object of the present invention is to provide a high-frequency circuit board, which comprises of at least one prepreg mentioned above and the copper foil cladded on both sides of the stacked prepregs.

The present invention has the following beneficial effects: \textcircled{1} in the thermosetting resin of the present invention, epoxy resin with specific molecular structure is adopted. It has high degree of functionality and the curing compound has low water absorption rate; \textcircled{2} in the present invention, active ester is adopted as curing agent for the epoxy resin composition, which has made fully use of the fact that the reaction of active ester and the epoxy do not produce polar groups, thereby the dielectric property and wet-heat resistance performance is good; the polyphosphonate ester or/and phosphonate carbonate copolymer with number average molecular weight of 1000-60000 is adopted as flame retardant, thereby halogen-free flame resistance is achieved and the flame resistance of the cured products reach UL 94 V-0 level, without sacrificing the heat resistance, low water absorption and excellent dielectric property of the original cured product, \textcircled{3} the prepreg and the copper-clad laminate of the present invention prepared with the thermosetting resin composition mentioned above has excellent dielectric properties, wet-heat resistance and flame resistance of UL 94 V-0 level.

### DETAILED DESCRIPTION

To better illustrate the present invention and understand technical solution of the present invention, the typical but non-limiting embodiments of the present invention are as follows:

Addressing the prepared copper clad laminate mentioned above, dielectric constant, dielectric loss factor, glass transition temperature and wet-heat resistance are all measured, and further described referring to the following embodiments.

### Embodiment 1

A container is taken, added with naphthol novolac epoxy resin NC-7300L (Nippon Kayaku, EEW is 214 g/eq) of 100 weight parts, then added with active ester curing agent HPC-8000-65T (Japan DIC, solid content is 65%) of 105 weight parts and stirred uniformly. Then it is added with flame retardant phosphonate carbonate copolymer FRX HM1100 (FRX Polymers, Phosphorus content is 10.8%) of 15 weight parts, then curing promotor DMAP of 0.075 weight parts and solvent toluene and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Embodiment 2

A container is taken, added with naphthol novolac epoxy resin NC-7000L (Nippon Kayaku, EEW is 232 g/eq) of 100 weight parts, then added with active ester curing agent HPC-8000-65T (Japan DIC, solid content is 65%) of 95 weight parts and stirred uniformly. Then it is added with flame retardant phosphonate oligomer compound OL5000(FRX Polymers, phosphorus content is 10.8%) of 65 weight parts, then curing promotor DMAP of 0.075 weight parts and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Embodiment 3

A container is taken, added with naphthol novolac epoxy resin HP-5000 (Japan DIC, EEW is 250 g/eq) of 100 weight parts, then added with active ester curing agent HPC-8000-65T (Japan DIC, solid content is 65%) of 90 weight parts and stirred uniformly. Then it is added with flame retardant phosphonate compound FRX OL3001(FRX Polymers, phosphorus content is 10.0%) of 55 weight parts, then curing promotor DMAP of 0.075 weight parts and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Embodiment 4

A container is taken, added with dicyclopentadiene phenolic epoxy resin HP-7200H (Japan DIC company, EEW is 278 g/eq) of 100 weight parts, then added with active ester curing agent EXA9460 (Japan DIC, solid content is 65%) of 79.6 weight parts and stirred uniformly. Then it is added with flame retardant phosphate carbonate copolymer compound FRX CO95(FRX Polymers, phosphorus content is 10.6%) of 65 weight parts, then curing promotor DMAP of 0.037 weight parts, silica powder of 60 weight parts and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Embodiment 5

A container is taken, added with arylaklylbenzenes type phenolic epoxy resin NC-2000L (Japan DIC company, EEW is 238 g/eq) of 100 weight parts, then added with active ester curing agent HPC-8000-65T (Japan DIC, solid content is 65%) of 93.7 weight parts and stirred uniformly. Then it is added with flame retardant phosphate carbonate copolymer compound FRX C095(FRX Polymers, phosphorus content is 10.6%) of 65 weight parts, then curing promotor DMAP of 0.075 weight parts, silica powder of 100 weight parts and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Embodiment 6

A container is taken, added with biphenyl type phenolic epoxy resin NC-3000H (Nippon Kayaku, EEW is 288 g/eq) of 100 weight parts, then added with active ester curing agent HPC-8000-65T (Japan DIC, solid content is 65%) of 77.5 weight parts and stirred uniformly. Then it is added with flame retardant phosphate carbonate copolymer compound FRX CO95 (FRX Polymers, phosphorus content is 10.6%) of 65 weight parts, then curing promotor DMAP of 0.075 weight parts, and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Embodiment 7

A container is taken, added with naphthol phenolic epoxy resin HP-6000 (Japan DIC company, EEW is 250 g/eq) of 100 weight parts, then added with active ester curing agent HPC-8000-65T (Japan DIC, solid content is 65%) of 90 weight parts and stirred uniformly. Then it is added with flame retardant phosphonate carbonate copolymer compound FRX OL3001 (FRX Polymers, phosphorus content is 10.0%) of 65 weight parts, then curing promotor DMAP of 0.075 weight parts, and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Embodiment 8

A container is taken, added with naphthol phenolic epoxy resin EXA-7318 (Japan DIC company, EEW is 250 g/eq) of 100 weight parts, then added with active ester curing agent HPC-8000-65T (Japan DIC, solid content is 65%) of 90 weight parts and stirred uniformly. Then it is added with flame retardant phosphate carbonate copolymer compound FRX CO95 (FRX Polymers, phosphorus content is 10.6%) of 80 weight parts, then curing promotor DMAP of 0.075 weight parts, and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Comparative Example 1

A container is taken, added with naphthol phenolic epoxy resin NC-7300L (Nippon Kayaku, EEW is 214 g/eq) of 100 weight parts, then added with active ester curing agent HPC-8000-65T (Japan DIC, solid content is 65%) of 105 weight parts and stirred uniformly. Then it is added with curing promotor DMAP of 0.075 weight parts, and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Comparative Example 2

A container is taken, added with phenol phenolic epoxy resin N690 (Japan DIC Company, EEW is 205 g/eq) of 50 weight parts, and high brominated epoxy resin BREN-105 (Nippon Kayaku, bromine content is 35%), then added with active ester curing agent HPC-8000-65T (Japan DIC, solid content is 65%) of 95 weight parts and stirred uniformly. Then it is added with curing promotor DMAP of 0.075 weight parts, and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Comparative Example 3

A container is taken, added with biphenyl phenolic epoxy resin NC-3000H (Nippon Kayaku, EEW is 288 g/eq) of 100 weight parts, then added with linear phenolic curing agent TD-2090 of 77.5 weight parts (Japan DIC, hydroxyl equivalent is 105 g/eq) and stirred uniformly. Then it is added with flame retardant phosphonate carbonate copolymer compound FRX CO95 (FRX Polymers, phosphorus content is 10.6%) of 65 weight parts, curing promotor DMAP of 0.075 weight parts, and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

### Comparative Example 4

A container is taken, added with biphenyl phenolic epoxy resin NC-3000H (Nippon Kayaku, EEW is 288 g/eq) of 100 weight parts, then added with active ester curing agent HPC-8000-65T (Japan DIC, solid content is 65%) of 77.5 solid weight parts, and stirred uniformly. Then it is added with flame retardant poly phosphate PX-200 (Daihachi Chemical, phosphorus content is 9%) of 65 weight parts, curing promotor DMAP of 0.075 weight parts, and solvent toluene, and is stirred uniformly to obtain a glue solution. Glass fiber cloth (model number: 2116, thickness: 0.08 mm) is impregnated into the glue solution mentioned above, controlled to an appropriate thickness, and then dried to remove the solvent to obtain the prepreg. Several pieces of prepared prepregs are stacked, one piece of copper foils is cladded for both sides of the stacked prepregs, and they are cured in a heat press machine to obtain a copper clad laminate. The cured temperature is 150-250° C., cured press is 25-60 kg/cm² and cured time is 90 min.

TABLE 1
Physical Property Data of Each Embodiment and Comparative Example

| | Embodiment | Embodiment | Embodiment | Embodiment | Embodiment | Embodiment |
|---|---|---|---|---|---|---|
| performance index | 1 | 2 | 3 | 4 | 5 | 6 |
| Tg(DMA)/□ | 170 | 172 | 155 | 175 | 160 | 165 |
| Dk(5G) | 3.8 | 3.8 | 3.8 | 3.7 | 3.9 | 3.9 |
| Df(5G) | 0.0065 | 0.007 | 0.007 | 0.0085 | 0.0075 | 0.007 |
| Water | 0.12 | 0.13 | 0.13 | 0.13 | 0.12 | 0.14 |
| absorption, % | | | | | | |
| Wet-heat resistance | 3/3 | 3/3 | 3/3 | 3/3 | 3/3 | 2/3 |
| Flame resistance | V-0 | V-0 | V-0 | V-0 | V-0 | V-0 |

TABLE 2
Physical Property Data of Each Embodiment and Comparative Example
(continued)

| performance | Embodiment | Embodiment | Comparative | Comparative | Comparative | Comparative |
|---|---|---|---|---|---|---|
| index | 7 | 8 | example 1 | example 2 | example 3 | example 4 |
| Tg(DMA)/□ | 185 | 180 | 170 | 165 | 155 | 115 |
| Dk(5G) | 3.85 | 3.85 | 3.9 | 4.0 | 4.1 | 3.95 |
| Df(5G) | 0.0075 | 0.0075 | 0.008 | 0.0085 | 0.020 | 0.009 |
| Water | 0.12 | 0.13 | 0.12 | 0.18 | 0.21 | 0.25 |
| absorption, % | | | | | | |
| Wet-heat | | | | | | |
| resistance | 3/3 | 3/3 | 3/3 | 3/3 | 3/3 | 1/3 |
| Flame | | | | | | |
| resistance | V-0 | V-0 | V-2 | V-0 | V-0 | V-0 |

The testing methods of performance above are as follows:

(1) glass transition temperature (Tg): measuring with DMA assay. Taking measurement with the DMA assay specified in IPC-TM-650 2.4.24;
(2) dielectric constant and dielectric loss factor: taking measurement with SPDR method;
(3) wet-heat resistance evaluation: evaluating the substrate lamina after the copper foil on the surface of copper-clad laminate was etched; placing the substrate lamina in a pressure cooker for treatment for 4 h, at 120° C., under 105 KPa; then impregnating the substrate lamina in a tin furnace at 288° C.; recording the corresponding time once the substrate lamina is delaminated; ending the evaluation if no bubble or delamination occurred after the substrate lamina was in a tin furnace for 5 min;
(4) flame resistance: measuring with UL94 standard method.

### Physical Properties Analysis

As shown by the property data of table 1, in comparative example 1, flame retardant is not added, and the active ester curing agent is adopted thereby good heat resistance and dielectric properties is achieved, but the flame resistance of grade V-0 level cannot be reached. In comparative example 3, traditional phenolic resin is adopted as curing agent, which will lead to generation of secondary hydroxyl after epoxy curing, thereby its dielectric properties is poor, and especially the dielectric loss tangent value is high. In comparative example 4, prior phosphate is adopted as the flame retardant. Although V-0 flame retardant requirements can be achieved, the plasticity of the phosphate ester will severely reduced glass transition temperature of the curing system. As shown by the comparison of embodiments 1-8, in the present invention, the phosphonate ester and/or phosphonate-carbonate copolymer with number average molecular weight of 1000-60000 is adopted as flame retardant, halogen-free flame resistance is achieve and the flame resistance of the cured products reach UL 94 V-0 level, without sacrificing the heat resistance, low water absorption and excellent dielectric property of the original cured product.

In summary, compared with the common copper-clad laminate, the copper-clad laminate of the present invention has excellent dielectric properties, higher glass transition temperature, and good wet-heat resistance, thus it is suitable for the application field of lead-free high speed communication.

The above are merely preferred embodiments of the present invention. Those skilled in the art can make numerous variations and changes according to the technical solution and spirit of the present invention, which all fall in the protection scope of the claims of the present invention.

The applicant stated that the present invention employ the embodiments above to describe the detailed components of the present invention, but the present invention is not limited to the detailed components above, i.e. it does not mean that the present invention must rely on the detailed components above to be implemented. Persons skilled in the art should understand, any improvement of the present invention, the equivalent replacement to the raw materials of the present invention product, adding auxiliary ingredients, specific mode selection, etc. all fall within the protection scope and disclosure scope of the present invention.

1. A thermosetting resin composition comprising of:
(A) epoxy resin;
(B) active ester curing agent;
(C) polyphosphonate ester or/and phosphonate-carbonate copolymer.

2. The thermosetting resin composition according to claim 1, wherein the structural formula of the polyphosphonates is as follows: 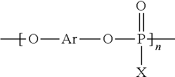
wherein Ar is an aryl, the —O-Ar-O— is any one selected from the group consisting of resorcinol active group, hydroquinone active group, bisphenol A active group, bisphenol F active group, 4,4′-bisphenol, phenolphthalein active group, 4,4′-thiodiphenol active group, 4,4′-sulfonyl diphenol active group and 3,3,5-trimethylcyclohexyl diphenol active group; X is selected from the group consisting of substituted or unsubstituted straight chain alkyl of C1-C20, substituted or unsubstituted branched alkyl of C1-C20, substituted or unsubstituted straight chain alkenyl of C2-C20, substituted or unsubstituted branched alkenyl of C2-C20, substituted or unsubstituted straight chain alkylene of C2-C20, substituted or unsubstituted branched alkylene of C2-C20, substituted or unsubstituted cycloalkyl of C5-C20, or substituted or unsubstituted branched aryl of C6-C20; n is any integer from 1 to 75.

3. The thermosetting resin composition according to claim 1, wherein the structural formula of the phosphonate-carbonate copolymer is as follows: 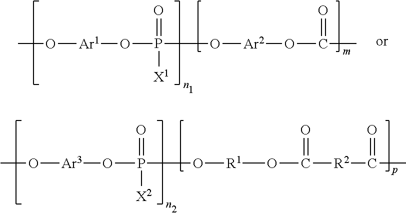
wherein, Ar¹, Ar² and Ar³ are respectively and independently selected from aryl and the -O-Ar³-O- is any one selected from the group consisting of resorcinol active group, hydroquinone active group, bisphenol A active group, bisphenol F active group, 4,4′-bisphenol, phenolphthalein activity group, 4,4′-thiodiphenol active groups, 4,4′-sulfonyl diphenol active group and 3,3,5-trimethylcyclohexyl diphenol active group; X¹ and X² are respectively and independently selected from substituted or unsubstituted straight chain alkyl of C1-C20, substituted or unsubstituted branched alkyl of C1-C20, substituted or unsubstituted straight chain alkenyl of C2-C20, substituted or unsubstituted branched alkenyl of C2-C20, substituted or unsubstituted straight chain alkylene C2-C20, substituted or unsubstituted branched alkylene of C2-C20, substituted or unsubstituted cycloalkyl of C5-C20, or substituted or unsubstituted branched aryl of C6-C20; m is any integer from 1 to 100, n₁ and n₂ are respectively and independently any integer from 1 to 75, and p is any integer from 2 to 50; R¹, R² are respectively and independently selected from the group consisting of substituted or unsubstituted aliphatic or aromatic hydrocarbon group,.

4. The thermosetting resin composition according to claim 1, wherein the polyphosphonate ester or/and phosphate-carbonate copolymer is any one or a mixture of at least two selected from the group consisting of 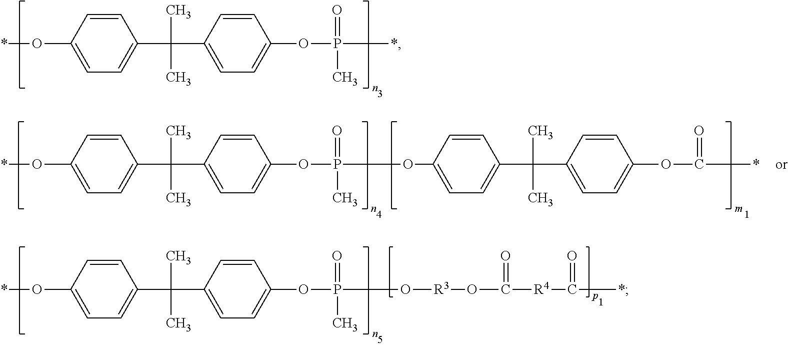
wherein, R³ and R⁴ are respectively and independently selected from substituted or unsubstituted aliphatic or aromatic hydrocarbon groups; m₁ is any integer from 1 to 100; n₃, n₄ and n₅ are respectively and independently any integer from 1 to 75; p₁ is any integer from 2 to 50.

5. The thermosetting resin composition according to claim 2, wherein, m and m₁ are respectively and independently any integer from 5 to 100.

6. The thermosetting resin composition according to claim 1, wherein the weight-average molecular weight of polyphosphonate ester or phosphonate-carbonate copolymer is 1000-60000.

7. The thermosetting resin composition according to claim 1, wherein the epoxy resin is selected from the epoxy resin with the following structure: 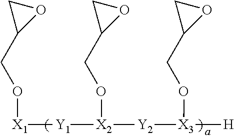
wherein, X₁, X₂, and X₃ are respectively and independently selected from 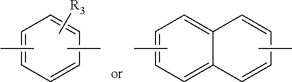
and R3 is any one selected from the group consisting of hydrogen atom, substituted or unsubstituted straight chain alkyl of C1-C5 and substituted or unsubstituted branched alkyl of C1-C5;
Y₁ and Y₂ are any one selected from the group consisting of single bond, —CH₂—, 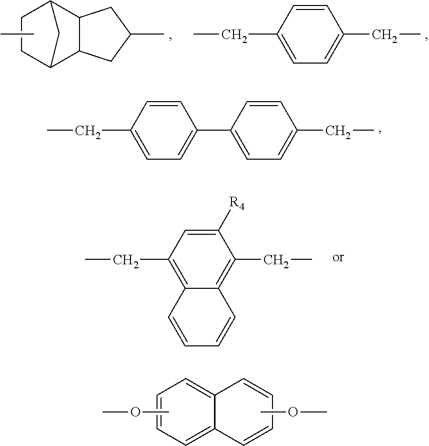
and R₄ is any one selected from the group consisting of hydrogen atom, substituted or unsubstituted straight chain alkyl of C1-C5 and substituted or unsubstituted branched alkyl and alkoxy of C1-C5; a is any integer from 1 to 10;

8. The thermosetting resin composition according to claim 1, wherein the epoxy resin is any one or a mixture of at least two selected from the epoxy resins having the following structural formula: 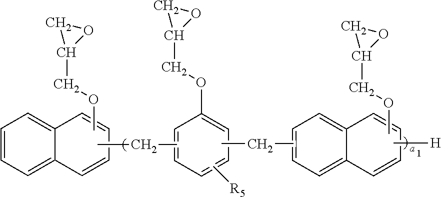
wherein, a₁ is any integer between 1 and 10, and R₅ is any one selected from the group consisting of hydrogen atom, substituted or unsubstituted straight chain alkyl of C1-C5 and substituted or unsubstituted branched alkyl of C1-C5;
or 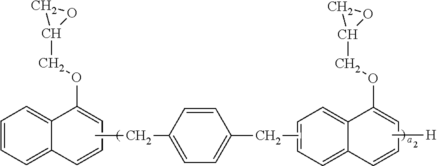
wherein, a₂ is any integer from 1 to 10;
or 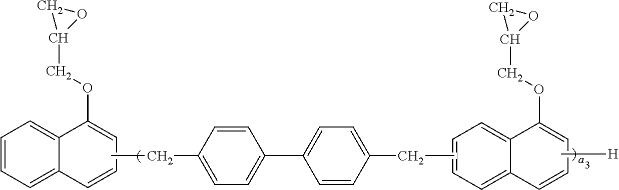
wherein, a₃ is any integer from 1 to 10;
or 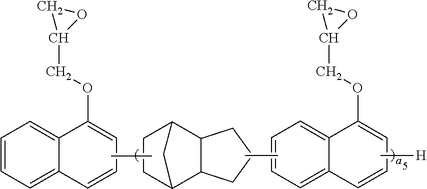
wherein, a4 is any integer from 1 to 10;

9. The thermosetting resin composition according to claim 1, wherein the epoxy resin is selected from the epoxy resin having the following structure: 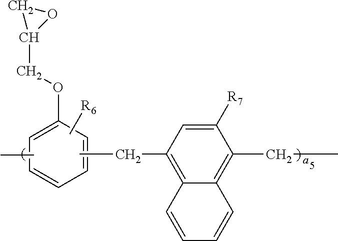
wherein, a₅ is any integer from 2 to 10, R₆ is any one selected from the group consisting of hydrogen atom, substituted or unsubstituted straight chain alkyl of C1-C5 or substituted or unsubstituted branched alkyl of C1-C5; R₇ is any one selected from the group consisting of hydrogen atoms, substituted or unsubstituted straight chain alkyl of C1-C5 or substituted or unsubstituted branched alkyl or alkoxy of C1-C5.

10. The thermosetting resin composition according to claim 1, wherein, the active ester curing agent is prepared from reaction of the phenolic compounds with structural formula of 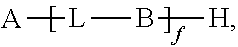
aromatic dicarboxylic acid or acid halides and monohydroxyl compounds; A, B are independently selected from phenolic groups, L is alicyclic group and f is any integer from 1 to 5;
the phenolic compounds with structural formula of 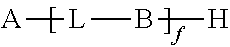
is any one or a mixture of at least two selected from the phenolic compounds having the following structure: 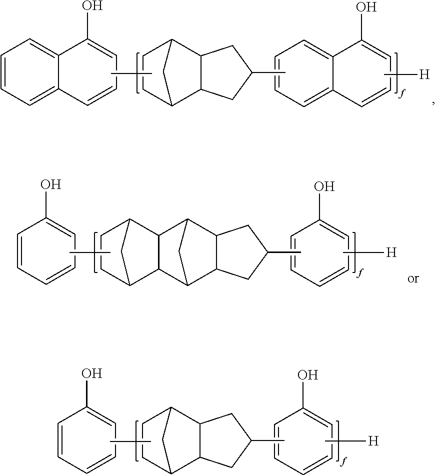
wherein, f is any integer from 1 to 5;
the aromatic dicarboxylic acid is any one or a mixture of at least two selected from the aromatic dicarboxylic acid having the following structure: 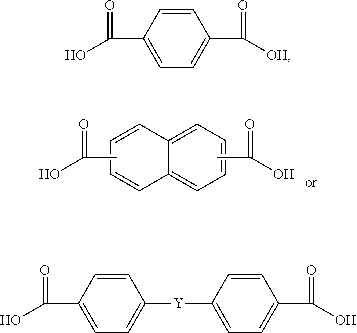
wherein, Y is selected from substituted or unsubstituted strain chain alkylene of C1-C5 or substituted or unsubstituted branched alkylene of C1-C5;
based on the usage amount of the aromatic dicarboxylic acid or acid halides as 1 mol, the usage amount of the phenolic compound with the structural formula of 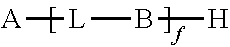
is 0.05-0.75 mol and the usage amount of monohydroxyl compounds is 0.25-0.95 mol.

11. The thermosetting resin composition according to claim 1, wherein the active ester curing agent has the structural formula as follows: 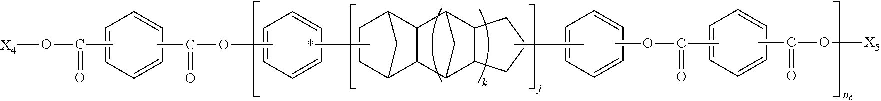
wherein, X₄ and X₅ are independently selected from benzene ring or naphthalene ring, j is 0 or 1, k is 0 or 1, and n₆ represents the average repeat unit of 0.25-2.5.

12. The thermosetting resin composition according to claim 1, wherein, based on the total weight of component (A) and component (B) as 100 weight parts, the polyphosphonate ester or/and phosphate-carbonate copolymer is 10-100 weight parts.

13. The thermosetting resin composition according to claim 1, wherein the equivalent ratio of the usage amount of the active ester curing agent is 0.85-1.2, based on the ratio of epoxy equivalent and active ester equivalent.

14. The thermosetting resin composition according to claim 1, wherein the thermosetting resin composition further comprises of (D) filler;
the filler is selected from organic or inorganic filler.

15. The thermosetting resin composition according to claim 14, wherein the inorganic filler is any one or a mixture of at least two selected from the group consisting of nonmetal oxide, metal nitride, non-metal nitride, inorganic hydrate, inorganic salt, metal hydrate and inorganic phosphorus;
the organic filler is any one or a mixture of at least two selected from the group consisting of polytetrafluoroethylene powder, polyphenylene sulfide, organophosphorus compounds and polyether sulfone powder;
the median particle diameter of the filler is 0.01-50 μm;
based on the total weight of the component (A), component (B) and component (C) of 100 weight parts, the addition amount of the filler is 5-1000 weight parts.

16. The thermosetting resin composition according to claim 1, wherein, the thermosetting resin composition further comprises of component (E) curing promotor;
the curing agent is any one or a mixture of at least two selected from the group consisting of imidazole compounds and their derivatives, piperidine compounds, lewis acid and triphenyl phosphine;
the imidazole compound is any one or a mixture of at least two selected from the group consisting of 2-methylimidazole, 2-phenylimidazole and 2-ethyl-4-methylimidazole;
the piperidine compound is any one or a mixture of at least two selected from a group consisting of 2,3-diaminopiperidine, 2,5-diaminopip eridine, 2,6-diaminopiperidine, 2,5-diaminopip eridine, 2-amino-3-ethylpiperidine, 2-amino-4-4-methylpiperidine, 2-amino-3-nitropiperidine, 2-amino-5-nitropiperidine or 4-dimethylaminopiperidine.

17. The thermosetting resin composition according to claim 16, wherein based on the total weight of the component (A), component (B) and component (C) of 100 weight parts, the addition amount of component (E) curing promotor is 0.01-1.0 weight parts.

18. A prepreg, wherein the prepreg comprises of the enhancement material and the thermosetting resin composition according to claim 1 which adhere to the enhancement material after impregnation and drying.

19. A laminate, wherein the laminate comprises of at least one prepreg according to claim 8.

20. A high-frequency circuit board, wherein the high-frequency circuit board comprises of at least one prepreg according to claim 8 and the copper foil covered on both sides of the stacked prepregs.
